(19) United States
(12) Patent Application Publication
(10) Pub. No.: US 2011/0049653 A1
(43) Pub. Date: Mar. 3, 2011

(54) MEMS SENSOR, ELECTRONIC DEVICE, AND METHOD OF MANUFACTURING MEMS SENSOR

(75) Inventor: Kei KANEMOTO, Suwa (JP)

(73) Assignee: SEIKO EPSON CORPORATION, Tokyo (JP)

(21) Appl. No.: 12/868,005

(22) Filed: Aug. 25, 2010

(30) Foreign Application Priority Data
Aug. 26, 2009 (JP) 2009-195121

(51) Int. Cl. H01L 29/84; H01L 21/302

(52) U.S. Cl. 257/417; 438/50; 257/E29.324; 257/E21.214

(57) ABSTRACT

An MEMS sensor includes: a fixation frame section; a movable weight section coupled to the fixation frame section via an elastically deformable section; a fixed electrode section extending from the fixation frame section toward the movable weight section; a movable electrode section extending from the movable weight section toward the fixation frame section, and disposed so as to be opposed to the fixed electrode section via a gap; a capacitance section composed mainly of the fixed electrode section and the movable electrode section; and an active element provided to the movable weight section.

### BACKGROUND

1. Technical Field

The present invention relates to a micro-electromechanical systems (MEMS) sensor, a method of manufacturing an MEMS sensor, an electronic device, and so on.

2. Related Art

JP-A-7-301640 (FIGS. 1 and 20, hereinafter referred to as a related art document), for example, discloses a semiconductor acceleration sensor having a capacitance sensor and a detection circuit (a peripheral circuit) formed on a semiconductor substrate.

If the capacitance sensor and the detection circuit (the peripheral circuit) are formed on the semiconductor substrate, the chip size increases due to the detection circuit (the peripheral circuit). Further, the length of the wiring from the capacitance sensor to the detection circuit also increases. Since the detection signal output from the capacitance sensor is a minute electric current signal, if the signal is attenuated due to the impedance of the wiring, the detection accuracy of the detection circuit is degraded.

### SUMMARY

An advantage of some aspects of the invention is to reduce the occupied area of the MEMS sensor, for example, and prevent degradation of the detection sensitivity of the MEMS sensor, for example.

1. According to a first aspect of the invention, there is provided an MEMS sensor including a fixation frame section, a movable weight section coupled to the fixation frame section via an elastically deformable section and having a hollow section formed in a periphery, at least one fixed electrode section fixed to the fixation frame section and constituting one of electrodes of a capacitive element, at least one movable electrode section moving integrally with the movable weight section, disposed so as to be opposed to the fixed electrode section, and constituting the other of the electrodes of the capacitive element, and a detection circuit provided to the movable weight section and having an amplifier circuit adapted to amplify a signal from the capacitive element. Further, according to another aspect of the invention, there is provided an MEMS sensor including a fixation frame section, a movable weight section coupled to the fixation frame section via an elastically deformable section, a fixed electrode section extending from the fixation frame section toward the movable weight section, a movable electrode section extending from the movable weight section toward the fixation frame section, and disposed so as to be opposed to the fixed electrode section via a gap, a capacitance section composed mainly of the fixed electrode section and the movable electrode section, and an active element provided to the movable weight section.

In the aspect of the invention, the movable weight section is provided with the detection circuit. Since the detection circuit is provided, the mass of the movable weight section is increased accordingly, and therefore, the detection sensitivity of the physical quantity such as acceleration is improved.

Further, the movable electrode section is formed integrally with the movable weight section. Since the movable weight section is provided with the detection circuit, the length of the wiring connecting between the movable electrode section and an input node of the detection circuit becomes extremely small, and thus the attenuation of the current signal (the electrical charge signal) from the movable electrode section can be reduced. The detection circuit includes at least an amplifier circuit (which can include, for example, a first stage charge/voltage converter circuit and a voltage amplifier for amplifying a voltage signal), and is able to efficiently amplify the signal from the movable electrode section. The signal thus amplified is led to the fixation frame section via, for example, the wiring disposed along the elastically deformable section (the spring section). Since the voltage amplitude of the signal is large enough, the attenuation of the signal in this case due to the wiring impedance can substantially be neglected, for example.

2. According to a second aspect of the invention, in the MEMS sensor of the above aspect of the invention, the movable weight section includes a substrate provided with an impurity layer and a first laminate structure formed on the substrate, the first laminate structure includes a plurality of insulating layers stacked, and a first conductor layer as an electrode, and a second conductor layer as wiring, the impurity layer provided to the substrate and the first conductor layer provided to the first laminate structure constitute at least one active element as a constituent of the amplifier circuit adapted to receive a signal from the capacitive element, and an input node of the active element is connected to one of one and the other electrodes of the capacitive element via the second conductor layer. Further, according to another aspect of the invention, in the MEMS sensor of the above aspect of the invention, the movable weight section includes a substrate provided with an impurity layer and a first laminate structure disposed on the substrate, the first laminate structure includes an insulating layer and a first conductor layer, and the active element is mainly composed of the impurity layer and the first conductor layer. Further, the movable electrode section is formed using the first conductor layer, and the first conductor layer is connected to the movable electrode section and the active element using a second conductor layer.

In this aspect of the invention, the movable weight section includes, for example, the substrate provided with the impurity layer and the first laminate structure formed on the substrate. The first laminate structure can easily be formed using, for example, the semiconductor manufacturing technology (e.g., a multilayer wiring forming technology), and can include, for example, a plurality of insulating layers and the first conductor layer to form the electrodes of the elements (e.g., the element constituting the detection circuit), and the second conductor layer to form the wiring layer (e.g., the wiring layer for connecting the different elements to each other). The impurity layer provided to the substrate and the first conductor layer provided to the first laminate structure constitute a constituent of the amplifier circuit (e.g., the first stage amplifier circuit) included in the detection circuit, and the at least one active element (e.g., the MOS transistor in the input stage) for receiving the signal from the capacitive element. The input node (the gate in the case in which the active element is an MOS transistor) of the active element is electrically connected to the electrode of the capacitive element (either one of the two electrodes) via the second conductor layer as the wiring layer.

In the aspect of the invention, the substrate (e.g., a silicon substrate) can be used as a weight. Therefore, it is possible to effectively increase the mass of the movable weight section. Therefore, it is possible to improve the detection sensitivity of the physical quantity (e.g., acceleration). Further, the mass of the movable weight section can be adjusted by controlling the thickness of the substrate, and in this case, it becomes possible to make the structure design of the MEMS sensor easier. Further, the first laminate structure on the substrate itself (including the electrode layer and the wiring layer constituting the detection circuit) makes a contribution to increase in the mass of the movable weight section.

Further, the second conductor layer (which can be the wiring formed only of the conductor layer in the same layer level, or can be a multilayer wiring having conductor layers in the different layer levels connected to each other with contact plugs) as the wiring disposed in the first laminate structure constituting the movable weight section is used for connecting the output electrode of the capacitive element and the input node of the active element to each other. Since the wiring length of the wiring using the second conductor layer is allowed to be short, the wiring resistance is reduced, and the attenuation of the current signal (the electrical charge signal) from the capacitive element can be minimized. Therefore, degradation of the detection sensitivity due to the wiring impedance can be reduced.

3. According to a third aspect of the invention, in the MEMS sensor of the above aspect of the invention, the fixed electrode section is constituted by a second laminate structure, which can be formed using the same manufacturing method as that of the first laminate structure and is articulated to the fixation frame section, the second laminate structure is formed so as to project from the fixation frame section toward the hollow section, a conductor layer composed of a plurality of conductor layers provided to the second laminate structure coupled to each other to form a wall-like first conductor surface constitutes one of the electrodes of the capacitive element, the movable electrode section is constituted by a third laminate structure, which can be formed using the same manufacturing method as that of the first laminate structure and is articulated to the first laminate structure, the third laminate structure is formed so as to project from the first laminate structure toward the hollow section, and a conductor layer composed of a plurality of conductor layers provided to the third laminate structure coupled to each other to form a wall-like second conductor surface constitutes the other of the electrodes of the capacitive element.

In the aspect of the invention, an example of the structure of the fixed electrode section and the movable electrode section is described. The fixed electrode section is constituted by the second laminate structure, and the movable electrode section is constituted by the third laminate structure. The second laminate structure and the third laminate structure are manufactured using the same manufacturing method as that of the first laminate structure constituting the movable weight section. In one example, a laminate structure is formed on the substrate, and then the laminate structure is etched by selective anisotropic etching, thereby simultaneously forming the first laminate structure of the movable weight section, the second laminate structure projecting from the fixation frame section toward the hollow section, and the third laminate structure projecting from the first laminate structure toward the hollow section.

The second laminate structure is provided with the conductor layer having the first conductor surface. The conductor layer having the first conductor surface forms the fixed electrode (one of the electrodes of the capacitive element). The first conductor surface is, for example, a wall-like surface extending along the projection direction of the second laminate structure, and is an opposed surface (specifically, one of the opposed surfaces of the both electrodes disposed so as to face each other with a predetermined gap) of the capacitor. For example, in the case in which the laminated conductor layer (a conductor structural object having a predetermined width in the plan view) provided to the second laminate structure extends (is disposed) in the projection direction of the second laminate structure, it is possible to define the side surface section (i.e., the wall-like surface having a predetermined area) of the conductor structural object as the first conductor surface. The first conductor surface is covered by, for example, an insulating film (it should be noted that the first conductor surface can also be exposed).

In other words, as described above, the first conductor surface can be configured by, for example, coupling a plurality of conductor layers, and the conductor layer (which can be rephrased as a laminate conductor layer, a laminate conductor structure, or a conductor structural object (a conductor structure)) is composed of, for example, the conductor layers in the first through nth layers (n denotes a natural number equal to or larger than 2) and the contact plugs for connecting the respective conductor layers coupled integrally to each other, and the sidewall surface of the conductor layer (a laminate conductor layer, a laminate conductor structure, or a conductor structural object (a conductor structure)) thus integrally coupled to each other can be used as the first conductor surface.

Similarly, the conductor layer having a wall-like second conductor surface is provided to the third laminate structure, and the second conductor surface forms the movable electrode (the other of the electrodes of the capacitive element). The second conductor surface is, for example, a wall-like surface extending along the projection direction of the third laminate structure, and is an opposed surface (specifically, the other of the opposed surfaces of the both electrodes disposed so as to face each other with a predetermined gap) of the capacitor. For example, in the case in which the laminated conductor layer (a conductor structural object having a predetermined width in the plan view) provided to the third laminate structure extends (is disposed) in the projection direction of the third laminate structure, it is possible to define the side surface section (i.e., the wall-like surface having a predetermined area) of the conductor structural object as the second conductor surface. The second conductor surface is covered by, for example, an insulating film (it should be noted that the second conductor surface can also be exposed).

In other words, the second conductor surface can be configured by, for example, coupling a plurality of conductor layers, and the conductor layer is composed of, for example, the conductor layers in the first through nth layers (n denotes a natural number equal to or larger than 2) and the contact plugs for connecting the respective conductor layers coupled integrally to each other, and the sidewall surface of the conductor layer thus integrally coupled to each other can be used as the second conductor surface.

In the aspect of the invention, the conductor layers are stacked using the multilayer wiring technology, and then processed using photolithography to form the conductor surface (i.e., each of the electrodes of the capacitive element) having a wall-like side surface in a simultaneous parallel manner, which makes the manufacturing process easier.

4. According to a fourth aspect of the invention, in the MEMS sensor of the above aspect of the invention, the first laminate structure is provided with an isolated conductor layer isolated electrically, and functioning as a mass adjusting layer of the movable weight section. Further, according to another aspect of the invention, in the MEMS sensor of the above aspect of the invention, the first laminate structure is provided with a dummy wiring layer floating electrically.

In the aspect of the invention, the first laminate structure is provided with the isolated conductor layer (the dummy conductor layer as an adjustment layer of the mass) having no contribution to the signal transmission. The conductor material (typically metal) has a specific gravity larger than that of the insulating material. Therefore, according to the present aspect, the mass of the movable weight section can effectively be increased, thus the detection sensitivity of the physical quantity can be improved.

5. According to a fifth aspect of the invention, in the MEMS sensor of the above aspect of the invention, the first laminate structure is provided with an isolated conductor layer, which is composed of a plurality of conductor layers coupled to each other, which has a wall-like cross-sectional surface, which functions as the mass adjustment layer of the movable weight section and a electromagnetic shield member, and which is isolated electrically.

In this aspect of the invention, the first laminate structure is also provided with the isolated conductor layer having no contribution to the signal transmission. It should be noted that the isolated conductor layer is composed of a plurality of conductor layers coupled to each other, provided with a wall-like cross-sectional surface, and functions as the mass adjustment layer of the movable weight section and the electromagnetic shield member. The isolated conductor layer functions as the mass adjustment layer of the movable weight section, and at the same time functions as the electromagnetic shield layer. For example, the isolated conductor layer is disposed along the periphery of the movable weight section, and the detection circuit is disposed inside the area surrounded by the isolated conductor layer. Thus, an effect (an electromagnetic shield effect) of shielding the electromagnetic wave from the detection circuit or the electromagnetic wave to the detection circuit can be obtained.

6. According to a sixth aspect of the invention, there is provided a method of manufacturing an MEMS sensor including a fixation frame section, a movable weight section coupled to the fixation frame section via an elastically deformable section and having a hollow section formed in a periphery, at least one fixed electrode section fixed to the fixation frame section and constituting one of electrodes of a capacitive element, at least one movable electrode section moving integrally with the movable weight section, disposed so as to be opposed to the fixed electrode section, and constituting the other of the electrodes of the capacitive element, and a detection circuit provided to the movable weight section and having an amplifier circuit adapted to output a voltage signal varying in accordance with a capacitance variation of the capacitive element, the method including the steps of (p) forming a laminate structure on the substrate, the laminate structure having the detection circuit, the one and the other of the electrodes of the capacitive element, and wiring adapted to connect an input node of the amplifier circuit of the detection circuit to one of the one and the other of the electrodes of the capacitive element, (q) patterning the laminate structure formed on the substrate by anisotropic etching to form a first opening section forming an opening section adapted to expose a surface of the substrate, to sectionalize, by the first opening section, the fixation frame section, the elastically deformable section, the movable weight section coupled to the fixation frame section via the elastically deformable section, the movable electrode section projecting from the movable weight section toward the first opening section, and the fixed electrode section projecting from the fixation frame section toward the first opening section so as to be opposed to the movable electrode section, and (r) inserting an etchant via the first opening section to selectively perform anisotropic etching on the substrate to form a second opening section communicated with the first opening section and penetrating the substrate to form a hollow section composed of the first opening section and the second opening section to thereby separate the movable weight section and the movable electrode section from the fixation frame section. Further, according to another aspect of the invention, there is provided a method of manufacturing an MEMS sensor including the steps of (a) providing an impurity layer to a substrate, (b) forming a laminate structure including an insulating layer and a conductor layer on the substrate, (c) patterning the laminate structure using anisotropic etching to form a first opening section from an uppermost layer of the laminate structure to a surface of the substrate, and (d) injecting an etchant via the first opening section to selectively perform anisotropic etching on the substrate to thereby form a second opening section penetrating the substrate, thus forming a fixation frame section, a movable weight section coupled to the fixation frame section via an elastically deformable section, a fixed electrode section extending from the fixation frame section toward the movable weight section, a movable electrode section extending from the movable weight section toward the fixation frame section, and disposed so as to be opposed to the fixed electrode section via a gap, a capacitance section composed mainly of the fixed electrode section and the movable electrode section, and an active element provided to the movable weight section.

In the aspect of the invention, the laminate structure is formed on the substrate, and the laminate structure is patterned with the anisotropic etching to form the first opening section for exposing the surface of the substrate. Thus, the laminate structure is sectionalized into the fixation frame section, the elastically deformable section, the movable weight section, the movable electrode section, and the fixed electrode section. Subsequently, by the injection of the etchant through the first opening section, the anisotropic etching is selectively performed on the substrate to form the second opening section communicated with the first opening section and penetrating the substrate. Thus, the movable weight section and the movable electrode section are separated from the fixation frame section. Further, the hollow section is composed of the first opening section and the second opening section. Since the hollow section is formed around the movable weight section, it becomes possible for the movable weight section (and the movable electrode section) to be displaced in accordance with the deformation of the elastically deformable section (the spring section).

It should be noted that in the state in which the anisotropic etching is performed on the substrate to form the second opening section, the substrate also remains beneath the movable weight section, the movable electrode section, the fixed electrode section, and the elastically deformable section (the spring section). The substrate of the movable weight section has a contribution to the increase in the mass as described above. Further, the substrate in the movable electrode section and the fixed electrode section acts to prevent the deformation of the electrode sections such as warpage due to the difference in thermal expansion coefficient between the materials constituting the electrodes from occurring (thus, the area fluctuation of the capacitive element). The substrate in the movable weight section has a function as the adjustment layer of the damping factor (the factor representing the degree of the damping caused by the phenomenon that the vibration of the movable weight section is hindered due to the air resistance). Further, the substrate in the elastically deformable section has an effect of preventing unwanted displacement such as twist or swing caused when the elastically deformable section is deformed from occurring.

It should be noted that, for example, there is a case in which the substrate in the elastically deformable section can be eliminated, and in such a case, the substrate located under the elastically deformable section with a small wiring width can completely be removed by performing isotropic etching on the substrate for a predetermined period of time (although peripheral portion of the substrate in the movable weight section is removed by the isotropic etching, the substrate in the central portion of the movable weight section remains unremoved). The modification of the etching process such as addition thereof as described above can arbitrarily be performed. These modified examples are all included in the aspect of the invention.

7. According to a seventh aspect of the invention, there is provided an electronic device including either one of the MEMS sensors described above.

The MEMS sensor according to this aspect of the invention has advantages that it is compact in size because the detection circuit is integrated in the movable weight section, that it is highly sensitive since the capacitance variation of the capacitive element can be detected by the detection circuit disposed closely, that it is easily manufactured because the semiconductor manufacturing process can be applied, and that it is moderate in price. Therefore, the electronic device equipped with this MEMS sensor also enjoys substantially the same advantages.

### BRIEF DESCRIPTION OF THE DRAWINGS

The invention will be described with reference to the accompanying drawings, wherein like numbers reference like elements.

FIG. 1 is a plan view showing a configuration of an example (here, a capacitive acceleration sensor) of an MEMS sensor according to the invention.

FIG. 2 is a diagram showing an example of a configuration of a detection circuit in the MEMS sensor (the capacitive acceleration sensor) shown in FIG. 1.

FIGS. 3A and 3B are diagrams showing a comparison between the size of the MEMS sensor (the capacitive acceleration sensor) shown in FIG. 1 and the size of an MEMS sensor (a capacitive acceleration sensor) of the related art.

FIG. 4 is a block diagram showing a configuration example of a detection circuit for the capacitive acceleration sensor.

FIGS. 5A through 5C are diagrams for explaining a configuration and an operation of an amplifier circuit.

FIGS. 6A and 6B are diagrams respectively showing a planar shape and a cross-sectional structure of a device in the state (a first process) in which a laminate structure is formed on a substrate.

FIGS. 7A and 7B are diagrams respectively showing the planar shape and the cross-sectional structure of the device in the state (a second process) in which the laminate structure on the substrate is patterned.

FIG. 8 is a diagram showing the planar shape and the cross-sectional structure of the device in the state (a third process) in which the substrate is patterned to separate a movable weight section and movable electrode sections from a fixation frame section.

FIG. 9 is a diagram showing a planar shape and a cross-sectional structure of an example (an example thereof having a structure in which the substrate remains in each of the movable weight section, elastically deformable sections, and the movable electrode sections) of the MEMS sensor (the acceleration sensor).

FIG. 10 is a diagram collectively showing examples of the advantage of the acceleration sensor according to the present embodiment.

FIG. 11 is a plan view of the MEMS sensor (the acceleration sensor) having a biaxial detection axis.

### DESCRIPTION OF EXEMPLARY EMBODIMENTS

Hereinafter, some preferred embodiments of the invention will be described in detail. It should be noted that the present embodiment explained below does not unreasonably limit the content of the invention as set forth in the appended claims, and all of the constituents set forth in the present embodiments are not necessarily essential as means for solving the problems of the invention.

### First Embodiment

Firstly, a configuration example of the MEMS sensor will be explained.

### Configuration of MEMS Sensor

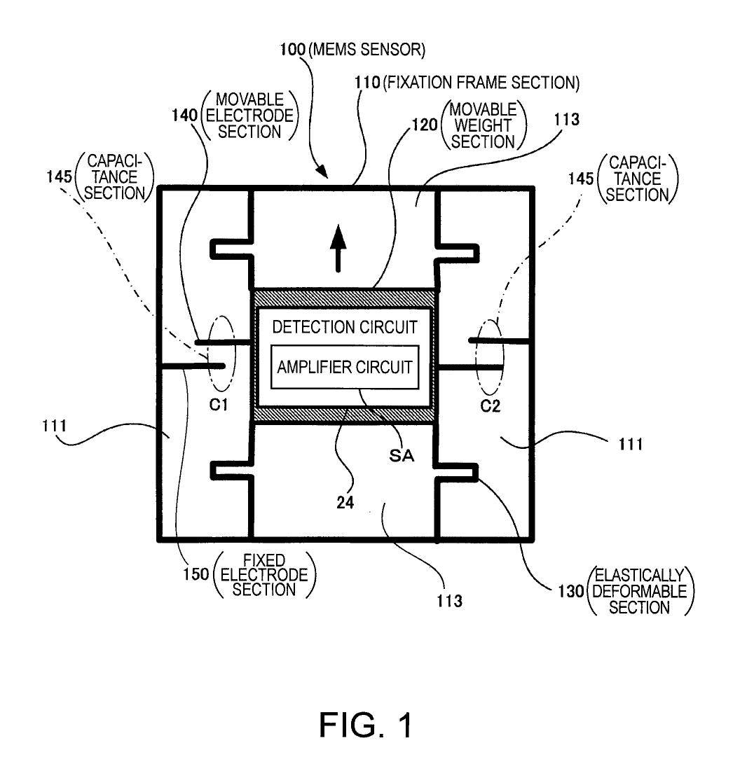

FIG. 1 is a plan view showing a configuration of an example (assumed here to be a capacitive acceleration sensor) of an MEMS sensor according to the invention. The MEMS sensor (the capacitive acceleration sensor) 100 shown in FIG. 1 can be manufactured by forming a laminate structure on a substrate, and then selectively processing the laminate structure and the substrate using a semiconductor manufacturing technology.

The capacitive acceleration sensor 100 includes a fixation frame section 110 (e.g., a silicon substrate), elastically deformable sections (spring sections) 130, a movable weight section 120 coupled to the fixation frame section 110 via the elastically deformable sections 130 with hollow sections 111, 113 formed in the periphery thereof, at least one fixed electrode section 150 fixed to the fixation frame section 110 and constituting one of electrodes of a capacitance section 145 (including a capacitive element C1 or a capacitive element C2), at least one movable electrode section 140 moving integrally with the movable weight section 120, and disposed so as to face the fixed electrode section 150, and constituting the other of the electrodes of the capacitance section 145 (the capacitive element C1 or the capacitive element C2), and a detection circuit 24 provided to the movable weight section 120. The detection circuit 24 has an amplifier circuit SA, to which signals (i.e., current signals (electrical charge signals) varying in accordance with the capacitance variation of the respective capacitive elements C1, C2)) from the capacitance sections 145 (the capacitive elements C1, C2) are input, and which amplifies the current signals (the electrical charge signals).

The movable electrode sections 140 are configured integrally with the movable weight section 120, and vibrates accordingly when the movable weight section 120 vibrates in response to the force caused by acceleration. In accordance thereto, the gaps (d) of the respective capacitance sections 145 (the capacitive elements C1, C2) are varied to vary the capacitance values of the respective capacitance sections (the capacitive elements C1, C2), and thus the migration of the charge is caused in accordance thereto. The value of the acceleration (a physical quantity) applied to the movable weight section 120 can be detected by amplifying the minute current caused by the migration of the charge by the amplifier circuit SA included in the detection circuit 24.

In the capacitive acceleration sensor 100 shown in FIG. 1, the mass of the movable weight section 120 increases in accordance with the detection circuit 24 provided to the movable weight section 120, which improves the detection sensitivity to the physical quantity such as acceleration. Further, the movable electrode sections 140 are formed so as to project from the movable weight section 120 toward the hollow section 111, and the movable weight section 120 is provided with the detection circuit 24. Therefore, the detection circuit 24 is inevitably disposed adjacent to the movable electrode sections 140. Therefore, the length of the wiring connecting between the movable electrode sections 140 and an input node of the detection circuit 24 becomes extremely small, and thus the attenuation of the current signal (the electrical charge signal) from the movable electrode sections 140 can be reduced.

The detection circuit 24 includes at least the amplifier circuit SA. The amplifier circuit SA includes, for example, a first stage charge/voltage converter circuit and a voltage amplifier for amplifying a voltage signal, and is able to efficiently amplify the signal from the movable electrode sections 140. The signal thus amplified is led to the fixation frame section 110 via, for example, the signal wiring (not shown in FIG. 1) disposed along the elastically deformable sections (the spring sections) 130. The attenuation of the signal in this case due to the wiring impedance can substantially be neglected since the voltage amplitude of the signal is large enough (i.e., amplified by the amplifier circuit SA).

### Regarding Detection Circuit Provided to Movable Weight Section And Laminate Structure of Movable Weight Section Etc.

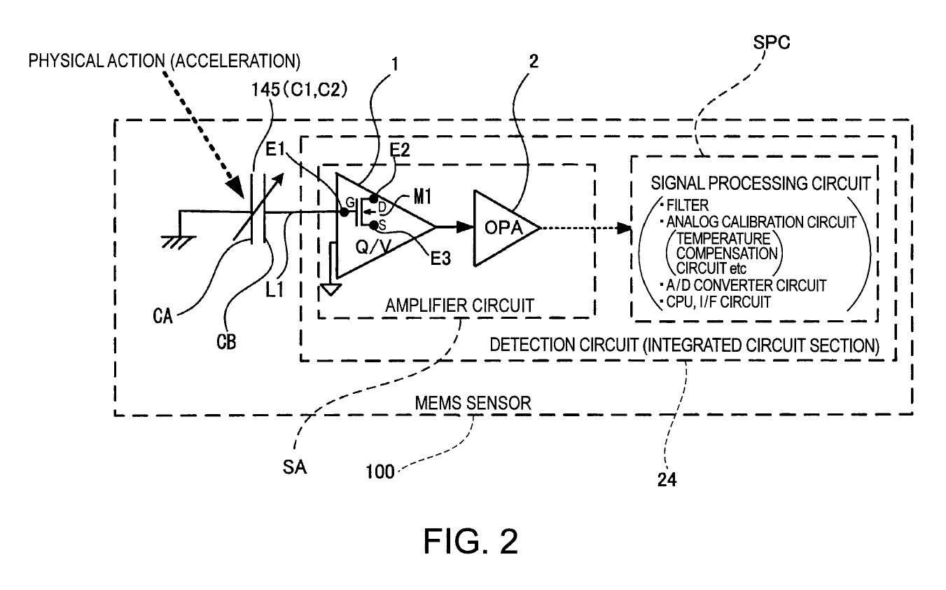

FIG. 2 is a diagram showing an example of a configuration of the detection circuit in the MEMS sensor (the capacitive acceleration sensor) shown in FIG. 1. One electrode CA of the capacitance section 145 (the variable capacitive element C1 or C2) is connected to a reference potential (e.g., ground potential), and the detection signal is output from the other electrode CB thereof (the other electrode CB functions as an output electrode). The capacitance section 145 (the variable capacitive element C1 or C2) and the detection circuit 24 are electrically connected by signal wiring L1.

The amplifier circuit SA in the detection circuit 24 includes a charge (current)/voltage conversion amplifier (a Q/V conversion amplifier) 1 and an amplifier (a voltage amplifier) 2 of at least one stage for receiving the electrical signal (the voltage signal) output from the Q/V conversion amplifier 1.

The Q/V conversion amplifier 1 can be configured as, for example, a switched-capacitor amplifier having an operational amplifier and a switched capacitor combined with each other. The Q/V conversion amplifier 1 has a first stage active element (assumed here to be an MOS transistor M1 as an example) for receiving the detection signal input via the signal wiring L1. A MOS transistor M1 is (but not limited to) a differential pair transistor (one of the differential pair transistors) for constituting a differential pair of a differential amplifier circuit in the first stage of the operational amplifier (a differential amplifier).

The MOS transistor M1 has a source (S) and a drain (D) formed of, for example, an impurity layer (e.g., a diffusion layer) provided to the substrate, and a gate (G) made of, for example, polysilicon, silicide, or refractory metal disposed on a thin gate insulating film (not shown) formed on the substrate. Further, a source electrode E3 is connected to the source (S), a drain electrode E2 is connected to the drain (D), and a gate electrode E1 is connected (including the case in which the gate G itself functions as the gate electrode E1) to the gate G. The impurity layer and the electrodes constitute the MOS transistor M1.

Further, the signal wiring L1 electrically connects the other electrode CB of the capacitance section 145 (the variable capacitive element C1 or C2) and the gate (G) of the MOS transistor M1 to each other.

It should be noted that the detection circuit 24 can further include a signal processing circuit SPC disposed on the posterior stage of the amplifier circuit SA (but is not limited thereto, and the signal processing circuit SPC can also be provided to the fixation frame section 110). The signal processing circuit SPC can include, for example, a filter, an analog calibration circuit (e.g., a temperature compensation circuit) for compensating the temperature characteristic, an A/D converter circuit, a CPU, an interface circuit I/F.

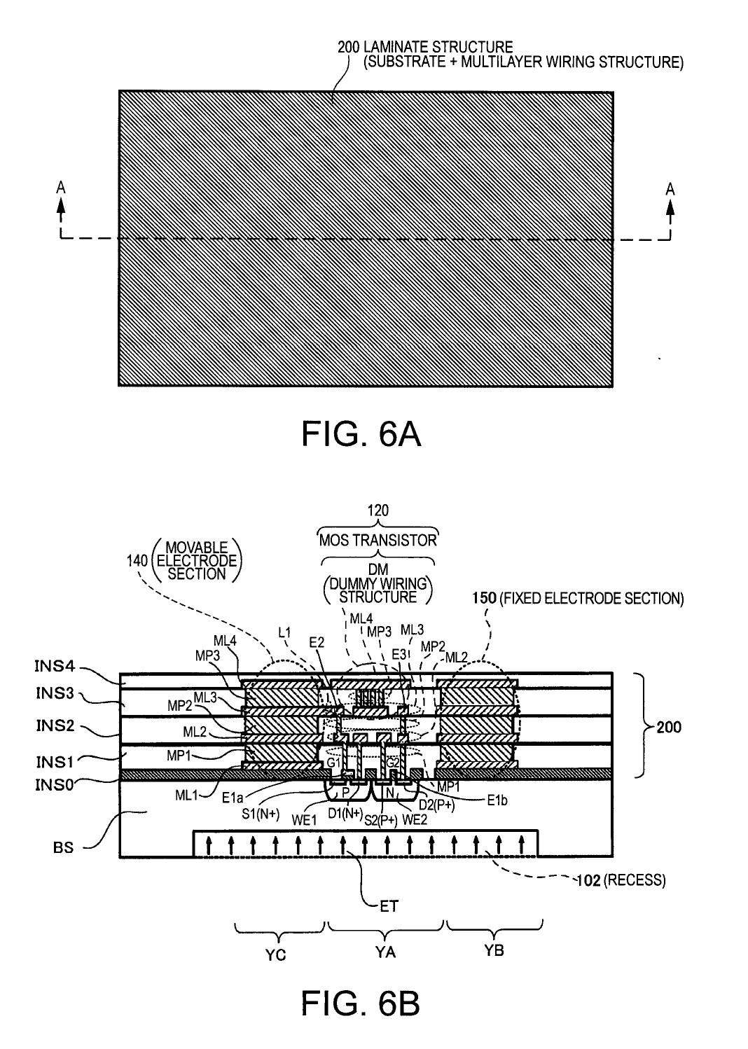

As described above, the capacitive acceleration sensor 100 shown in FIG. 1 can be formed utilizing a semiconductor manufacturing technology. Specifically, the movable weight section 120 can be composed of the substrate provided with the impurity layer, and a first laminate structure having a plurality of insulating layers stacked on the substrate and a first conductor layer as the electrodes (e.g., E1 through E3) and a second conductor layer as the wiring (e.g., the signal wiring L1) formed thereon (a specific structure and a manufacturing method thereof will be explained later with reference to FIGS. 6A, 6B, 7A, 7B, and 8). Further, the amplifier circuit SA is formed of the impurity layer provided to the substrate and the first conductor layer provided to the first laminate structure (i.e., the constituents of the amplifier circuit SA), and at the same time, at least one active element (a first stage MOS transistor M1) for receiving the signals (the detection signals) from the capacitance sections 145 (C1, C2) is formed thereof, the input node (the gate electrode E1) of the active element (the MOS transistor M1) being connected to either one (the electrode CB here) of the electrodes of the capacitance 145 (C1, C2) via the second conductor layer L1.

In other words, the movable weight section 120 includes, for example, the substrate provided with the impurity layer and the laminate structure formed on the substrate. Further, the first laminate structure constituting the movable weight section 120 can easily be formed using, for example, the semiconductor manufacturing technology (e.g., a multilayer wiring forming technology), and can include, for example, a plurality of insulating layers and the first conductor layer to form the electrodes (E1 through E3) of the elements (e.g., the element M1 constituting the detection circuit 24), and the second conductor layer to form the wiring layer (e.g., the wiring layer for connecting the different elements to each other, such as L1). The impurity layer provided to the substrate and the first conductor layer provided to the first laminate structure constitute the amplifier circuit (e.g., the first stage amplifier circuit) SA included in the detection circuit 24, and the at least one active element (e.g., the MOS transistor M1 in the input stage) for receiving the detection signals from the capacitance sections 145 (C1, C2).

The input node (the gate electrode E1 in the case in which the active element is the MOS transistor M1) of the active element is electrically connected to the electrode (either one of the two electrodes; the electrode CB in FIG. 2) of the capacitance sections 145 (C1, C2).

It should be noted that although the case in which the first conductor layer included in the first laminate structure is used as the electrodes (E1 through E3) of the first stage MOS transistor M1 is explained above, this is nothing more than an example. The amplifier circuit SA is generally composed of a plurality of active elements (transistors) and a plurality of passive elements (e.g., resistors). It is deservingly possible to form the electrodes of each of these elements with the first conductor layer, and to constitute the wiring for electrically connecting these elements to each other with the second conductor layer. Further, each of the first conductor layer and the second conductor layer can be a conductor layer belonging to either one of the layers of the multilayer wiring structure, or can be a wiring structure having a multilayer structure composed of a plurality of conductor layers in different layers connected to each other with contact plugs.

According to the MEMS sensor (the capacitive acceleration sensor) 100 of the present embodiment, the substrate (e.g., a silicon substrate) can be used as the weight. Therefore, it is possible to effectively increase the mass of the movable weight section. Therefore, it is possible to improve the detection sensitivity of the physical quantity (e.g., acceleration). Further, the mass of the movable weight section can be adjusted by controlling the thickness of the substrate, and in this case, it becomes possible to make the structure design of the MEMS sensor easier.

Further, the first laminate structure on the substrate itself (including the electrode layer and the wiring layer constituting the detection circuit 24) makes a contribution to increase in the mass of the movable weight section 120. The mass of the movable weight section can be adjusted (further, the damping coefficient can also be possible at the same time) by controlling the thickness of the first laminate structure.

Further, the second conductor layer (which can be the wiring formed of the conductor layer of the same layer or the multilayer wiring composed of conductor layers in the different levels connected to each other with the contact plugs or the like as described above) as the wiring disposed in the first laminate structure constituting the movable weight section 120 can be used for connecting the output electrode CB of the capacitance sections 145 (the variable capacitive elements C1, C2) and the input node (E1) of the active element (MOS transistor M1) to each other. Since the detection circuit 24 can be disposed adjacent to the movable electrode sections 140, the length of the wiring L1 formed of the second conductor layer is allowed to be short. Therefore, it is possible to minimize the attenuation of the electrical charge signal (the current signal) from the capacitance sections 145 (C1, C2), and therefore, it becomes possible to prevent degradation of the detection sensitivity due to the wiring impedance.

### Advantages of Present Embodiment

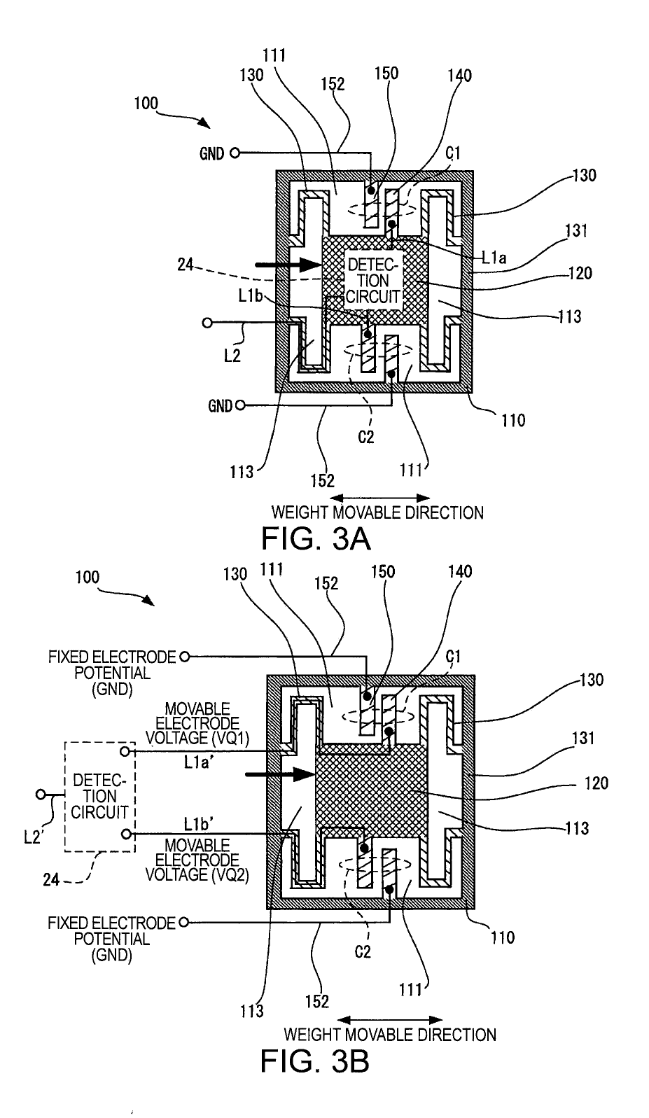

FIGS. 3A and 3B are diagrams showing a comparison between the size of the MEMS sensor (the capacitive acceleration sensor) shown in FIG. 1 and the size of an MEMS sensor (a capacitive acceleration sensor) of the related art. FIG. 3A shows the capacitive acceleration sensor according to the present embodiment, and FIG. 3B shows an example (related art example using the technology of the related art document mentioned above) of disposing the detection circuit (the peripheral circuit including the detection circuit) in the periphery of the sensor. In FIGS. 3A and 3B, the constituents corresponding to those shown in FIG. 1 are denoted with the same reference symbols. In the drawings, the reference symbols L1a, L1b, and L1a′, L1b′ denote the signal wiring connecting the capacitance sections 145 (C1, C2) to the detection circuit 24, and further, the reference symbols L2, L2′ denote the output wiring for leading out the output signal of the detection circuit 24.

When comparing FIGS. 3A and 3B with each other, it is obvious that the size (the occupied area in the plan view) of the sensor module (the sensor device composed of the sensor section and the detection circuit section integrated with each other) shown in FIG. 3A is reduced as much as the size of the detection circuit 24 disposed in the movable weight section 120. Further, in FIG. 3A, the length of the wiring L1a, L1b connecting the movable electrode sections 140 and the detection circuit 24 is extremely short, and therefore, the attenuation of the detection signal due to the wiring impedance can be suppressed to a low level. In FIG. 3B, the wiring for connecting the movable electrode sections 140 and the detection circuit 24 with each other is denoted by the symbols L1a′, L1b′, and it is obvious that L1a<L1a′, L1b<L1b′ are satisfied. The electrical charge signal (the current signal) generated due to the variation in capacitances of the capacitance sections 145 (C1, C2) is an extremely minute signal, and it makes a contribution to improvement of the S/N ratio of the detection circuit 24 to input the minute detection signal to the amplifier circuit SA while minimizing the attenuation (loss) thereof.

### Regarding Configuration Example of Detection Circuit for Acceleration Sensor

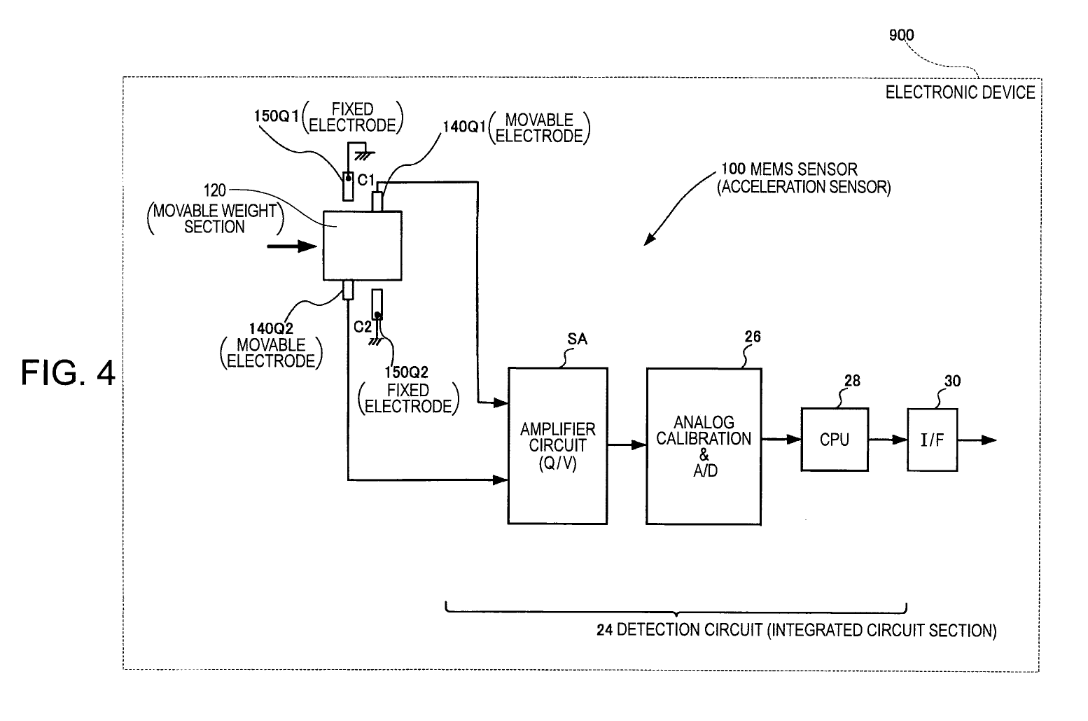

FIG. 4 is a block diagram showing a configuration example of a detection circuit for the capacitive acceleration sensor. The acceleration sensor 100 has at least two pairs of movable and fixed electrodes. In FIG. 4, there are provided the first movable electrode section 140Q1, the second movable electrode section 140Q2, the first fixed electrode section 150Q1, and the second fixed electrode section 150Q2. The capacitor C1 is composed of the first movable electrode section 140Q1 and the first fixed electrode section 150Q1. The capacitor C2 is composed of the second movable electrode section 140Q2 and the second fixed electrode section 150Q2. The potential of one (e.g., the fixed electrode section) of the electrode sections in each of the capacitors C1, C2 is fixed to a reference potential (e.g., the ground potential). It should be noted that it is also possible to fix the potential of the movable electrode sections to the ground potential, and to obtain the detection signal from the fixed electrode section.

The detection circuit (an integrated circuit section) 24 is formed using, for example, a CMOS process. The detection circuit (the integrated circuit section) 24 can include the amplifier circuit SA, an analog calibration and A/D conversion circuit unit 26, a central processing unit (CPU) 28, and an interface (I/F) circuit 30. It should be noted that this configuration is nothing more than an example, and the invention is not limited to this configuration. For example, the CPU 28 can be replaced with a control logic circuit, and the A/D converter circuit can also be disposed in the output stage of the amplifier circuit SA. It should be noted that the A/D converter circuit and the CPU can also be disposed in another integrated circuit different from the detection circuit (the integrated circuit section) 24.

When the acceleration acts on the movable weight section 120 at rest, then the force due to the acceleration acts on the movable weight section 120, and the gaps of the respective pairs of movable and fixed electrodes are varied. If the movable weight section 120 migrates in the arrow direction shown in FIG. 4, the gap between the first movable electrode section 140Q1 and the first fixed electrode section 150Q1 increases while the gap between the second movable electrode section 140Q2 and the second fixed electrode 150Q2 decreases. Since the gap and the capacitance have an inversely proportional relationship, the capacitance value C1 of the capacitor C1 composed of the first movable electrode section 140Q1 and the first fixed electrode section 150Q1 decreases, while the capacitance value C2 of the capacitor C2 composed of the second movable electrode section 140Q2 and the second fixed electrode section 150Q2 increases.

The migration of the charge is caused in accordance with the variation of the capacitance values of the capacitors C1, C2. The amplifier circuit SA has a charge amplifier using, for example, a switched capacitor, and the charge amplifier converts a minute current signal caused by the migration of the charge into a voltage signal with a sampling action and an integral (amplifying) action. The voltage signal (i.e., a physical quantity signal detected by a physical quantity sensor) output from the amplifier circuit SA undergoes the calibration process (e.g., an adjustment of the phase and the signal amplitude, and possibly a low-pass filter process in addition thereto) by the analog calibration and A/D conversion circuit unit 26, and is then converted from the analog signal to the digital signal.

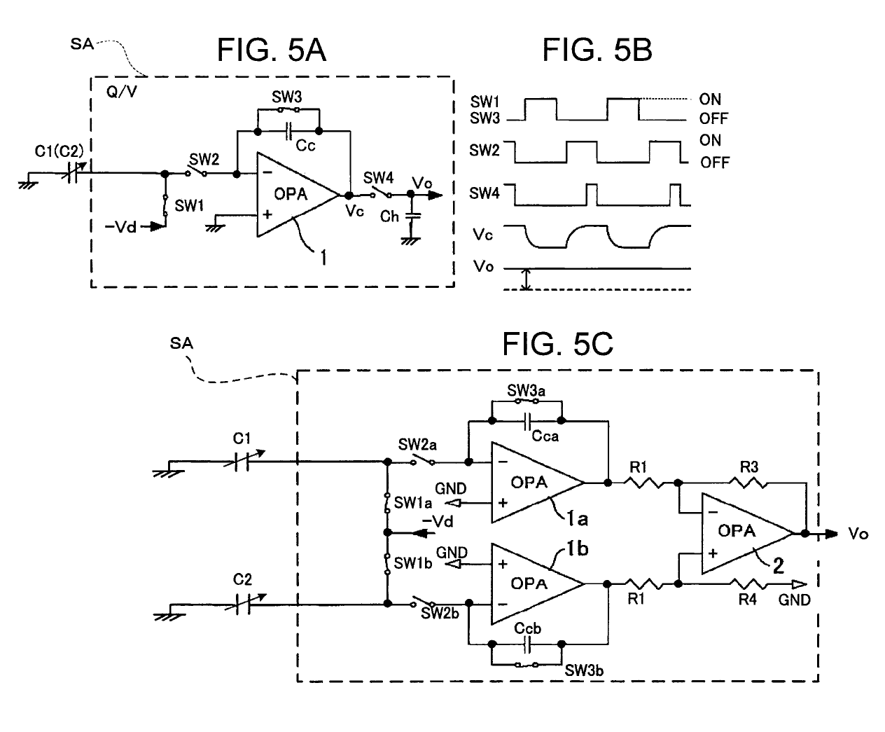

Here, an example of the configuration and the operation of the amplifier circuit SA will be explained with reference to FIGS. 5A through 5C. FIG. 5A is a diagram showing a basic configuration of the Q/V conversion amplifier (the charge amplifier) using the switched capacitor, and FIG. 5B is a diagram showing voltage waveforms in the respective sections of the Q/V conversion amplifier shown in FIG. 5A.

As shown in FIG. 5A, the basic Q/V converter circuit (Q/V conversion amplifier) has first and second switches SW1, SW2 (constituting the switched capacitor in the input section together with the variable capacitive element C1 (or C2)), the operational amplifier (OPA) 1, a feedback capacitor (an integral capacitance) Cc, a third switch SW3 for resetting the feedback capacitor Cc, a fourth switch SW4 for sampling the output voltage Vc of the operational amplifier (OPA) 1, and a holding capacitor Ch.

As shown in FIG. 5B, ON/OFF control of the first switch SW1 and the third switch SW3 is performed using a first clock in an in-phase manner, and ON/OFF control of the second switch SW2 is performed using a second clock having a reverse phase with respect to the first clock. The fourth switch SW4 is turned ON for a short period of time at the end of the period during which the second switch SW2 is kept ON. When the first switch SW1 is turned ON, a predetermined voltage Vd is applied to the both ends of the variable capacitive element C1 (C2), and the charge is stored in the variable capacitive element C1 (C2). In this case, since the third switch is in the ON state, the feedback capacitor Cc is in a reset state (the state in which the both ends are shorted). Subsequently, when the first switch SW1 and the third switch SW3 are turned OFF, and the second switch SW2 is turned ON, the both ends of the variable capacitive element C1 (C2) are set to be the ground potential, and therefore, the charge stored in the variable capacitive element C1 (C2) migrates toward the operational amplifier (OPA) 1. In this case, since the amount of the charge is maintained, Vd·C1 (C2)=Vc·Cc is satisfied, and therefore, (C1/Cc)·Vd is obtained as the output voltage Vc of the operational amplifier (OPA) 1. In other words, the gain of the charge amplifier is determined in accordance with the ratio between the capacitance value of the variable capacitive element C1 (or C2) and the capacitance value of the feedback capacitor Cc. Subsequently, when the fourth switch (a sampling switch) SW4 is turned ON, the output voltage Vc of the operational amplifier (OPA) 1 is held by the holding capacitor Ch. The voltage thus held is the voltage V0, and the voltage V0 is regarded as the output voltage of the charge amplifier.

As shown in FIG. 4, the actual amplifier circuit SA receives a differential signal from the two capacitors C1, C2. In this case, the charge amplifier having such a differential configuration as shown in FIG. 5C can be used as the amplifier circuit SA. In the charge amplifier shown in FIG. 5C, there are provided in the input stage a first switched-capacitor amplifier (SW1a, SW2a, OPA1a, Cca, SW3a) for amplifying the signal from the variable capacitive element C1, and a second switched-capacitor amplifier (SW1b, SW2b, OPA1b, Ccb, SW3b) for amplifying the signal from the variable capacitive element C2. Then, the respective output signals (the differential signal) of the operational amplifier (OPA) 1a, 1b are input to a differential amplifier (OPA2, resisters R1 through R4) disposed in the output stage. As a result, the output signal Vo thus amplified is output from the operational amplifier (OPA) 2. By using the differential amplifier, there can be obtained an advantage that the base noise (the common-mode noise) can be removed.

It should be noted that the configuration example of the amplifier circuit SA described hereinabove is illustrative only, and the invention is not limited to this configuration. Further, although the two pairs of movable and fixed electrodes are only illustrated in FIGS. 4 and 5C for the sake of convenience of explanation, the invention is not limited to this example, but the number of pairs of electrodes can be increased in accordance with the value of the capacitance required. In practice, there are provided several tens through several hundreds pairs of electrodes, for example. Further, although in the example described above the capacitance of each of the capacitors varies due to the variation of the gap between the electrodes in the capacitors C1, C2, the invention is not limited thereto, but there can also be adopted a configuration in which the opposed areas of two movable electrodes with respect to one reference electrode vary to thereby vary the capacitances of the two capacitors C1, C2 (this configuration is advantageous for the case of, for example, detecting the acceleration acting in the Z-axis direction (the direction perpendicular to the substrate)).

### Second Embodiment

In the present embodiment, an example of a method of manufacturing a capacitive MEMS acceleration sensor will be explained. Hereinafter, an outline of the method of manufacturing the acceleration sensor module shown in FIG. 3A will be explained with reference to FIGS. 6A, 6B, 7A, 7B, and 8.

### First Process

FIGS. 6A and 6B are diagrams respectively showing a planar shape and a cross-sectional structure of the device in the state (a first process) in which a laminate structure is formed on a substrate. FIG. 6A is a plan view, and FIG. 6B is a cross-sectional view of the device shown in FIG. 6A along the line A-A.

In the first process (process 1), the reverse surface of the semiconductor substrate (a silicon substrate) BS is selectively etched to adjust the thickness of the silicon substrate BS, and then the laminate structure including a plurality of conductor layers and a plurality of insulating layers is formed on the silicon substrate BS using a CVD method. Hereinafter, the process will specifically be explained step by step. In the following description, the structure of the CMOS transistor and the structure of the wiring provided to the laminate structure will be mentioned.

As shown in FIG. 6B, firstly, anisotropic etching is selectively performed on the reverse surface of the silicon substrate BS using an etchant ET for the anisotropic etching in the condition in which the silicon substrate BS stands alone without any attachments. Specifically, the anisotropic etching is performed selectively on the inside of the portion to be formed as the fixation frame section 110. As the anisotropic etching process, dry etching can be used, and further, alkali etching (wet etching) using KOH can also be used. By the selective anisotropic etching on the silicon substrate BS, a recess 102 is provided to the reverse surface of the silicon substrate BS.

It should be noted that the recess 102 provided to the reverse surface of the silicon substrate BS is not necessarily required. If the silicon substrate BS has an appropriate thickness from the beginning, the recess 102 is not required. However, it is preferable to appropriately control the thickness of the silicon substrate BS in accordance with the design value (the mass of the movable weight section) of the acceleration sensor, for example, and therefore, it is preferable to provide the recess 102. Further, if the recess 102 exists, a leg section with a step corresponding to the depth of the recess 102 can be formed. Therefore, it is preferable on the ground that the movable weight section 120 can be prevented from having contact with the installation surface.

Subsequently, the laminate structure 200 is formed on the silicon substrate BS using the semiconductor manufacturing technology. The laminate structure 200 includes a plurality of insulating layers INS0 through INS4 stacked in respective layers different from each other. In other words, the laminate structure 200 includes the insulating layer INS0 as a surface protective film, the interlayer insulating films INS1 through INS3, and the insulating layer INS4 as an ultimate protective film. Each of the insulating layers can be formed by depositing the material such as NSG, BPSG, SOG, or TEOS with a film thickness of 10,000 through 20,000 Å using the CVD process.

Further, in the laminate structure 200, the central portion corresponding to the movable weight section 120 corresponds to a first laminate structure YA, the portions corresponding to the fixed electrode sections 150 correspond to a second laminate structure YB, and the portions corresponding to the movable electrode sections 140 correspond to a third laminate structure YC. It should be noted that the laminate structure 200 is sectionalized or separated into the first laminate structure YA through the third laminate structure YC later by an etching process.

Further, the first laminate structure YA is provided with the first conductor layer to form the electrodes (including the contact plugs) of the active elements (e.g., transistors) and the passive elements (e.g., resistors) constituting the detection circuit 24, and the second conductor layer to form the wiring for electrically connecting different elements to each other using the multilayer wiring technology. The electrodes and the wiring can be formed by depositing a metal material (or silicide or polycide) such as Al, and then patterned by photolithography. Further, the contact plugs for connecting the electrode layers (or wiring layers) in different layers can be formed by, for example, plugging the through holes (embedded grooves) formed in the insulating layers with a conductive material such as W, TiW, or TiN using a sputtering or CVD process, and then removing the conductive material on the insulating layers using an etching-back process.

Further, in the example shown in FIG. 6B, there is formed a dummy wiring layer DM (an isolated wiring layer without electrical connections with other elements) as an adjustment layer having a function of adjusting the mass of the movable weight section 120. Although it is not essential to provide the dummy wiring layer DM, there is an advantage, for example, that it becomes easy to design the acceleration sensor since the mass of the movable weight section 120 can easily be increased by providing the dummy wiring layer DM.

In FIG. 6B, an MOS transistor (a CMOS transistor) is illustrated as an active element. In other words, the silicon substrate BS is provided with a P-well WE1 and an N-well WE2, wherein the P-well WE1 is provided with a source layer S1 of an N+ type and a drain layer D1 of the N+ type, and the N-well WE2 is provided with a source layer S2 of a P+ type and a drain layer D2 of the P+ type. Further, in the channel region between the source layer S1 of the N+ type and the drain layer D1 of the N+ type, there are formed a thin gate oxide film (the symbol is omitted) on the surface of the silicon substrate BS, and a gate electrode E1a made of polysilicon or metal on the gate oxide film, thus a gate G1 is configured. Similarly, in the channel region between the source layer S2 of the P+ type and the drain layer D2 of the P+ type, there are formed a thin gate oxide film (the symbol is omitted) on the surface of the silicon substrate BS, and a gate electrode E1b made of polysilicon or metal on the gate oxide film, thus a gate G2 is configured.

Further, as the conductor layer for constituting the multilayer wiring structure, there can be cited, for example, a contact plug MP1 embedded in the contact hole penetrating the insulating layers INS0 and INS1, second layer wiring layer ML2, a contact plug MP2 embedded in the contact hole (through hole) penetrating the insulating layer INS2, third layer wiring layer ML3, a contact plug MP3 embedded in the contact hole penetrating the insulating layer INS3, and fourth layer wiring layer ML4.

All of the gate electrodes E1a, Fib forming the gates G1, G2, the contact plug MP1, the second layer wiring layer ML2, the contact plug MP2, and the third layer wiring layer ML3 (parts thereof function as the source electrode E1 and the drain electrode E3 of the MOS transistor, respectively) can be called the first conductor layer for forming the electrodes of the MOS transistor.

Further, as shown in FIG. 6B, the movable electrode sections 140 and the fixed electrode sections 150 are formed adjacent to the movable weight section 120. The movable electrode sections 140 and the fixed electrode sections 150 are each formed of a conductive structure (a conductive structural object) having a wall-like cross-sectional surface (a wall-like surface with a predetermined area). The conductive structure (the conductive structural object) is composed of the first layer wiring layer ML1, the contact plug MP1, the second layer wiring layer ML2, the contact plug MP2, the third layer wiring layer ML3, the contact plug MP3, and the fourth layer wiring layer ML4 stacked one another. The movable electrode sections 140 having a wall-like surface have an advantage of effectively increasing the mass of the movable weight section 120. The movable electrode sections 140 each have both of the function as the “movable electrode” and the function as the “movable weight,” and therefore, can be called a “movable electrode/weight section.”

Further, in FIG. 6B, the third layer wiring layer ML3 constituting the movable electrode sections 140 (the movable electrode) is drawn to the side of the movable weight section 120 (the side of the dummy wiring layer DM), and the wiring thus drawn forms the signal wiring L1 (the second conductor layer as the wiring) for connecting the movable electrode sections 140 and the amplifier circuit SA of the detection circuit 24 to each other. In FIG. 6B, the signal wiring (the second conductor layer) L1 is connected to the gate G1 (the first conductor layer as the electrode E1a) of the NMOS transistor in the input stage of the first-stage amplifier 1 of the amplifier circuit SA. As described above, since the length of the signal wiring L1 is small, the attenuation of the detection signal due to the wiring impedance can be reduced.

It should be noted that the dummy wiring layer DM (the isolated conductor layer) is composed of a part of the third layer wiring layer ML3, the contact plug MP3, and the fourth layer wiring layer ML4. As described above, the dummy wiring layer DM (the isolated conductor layer) has an advantage of increasing the mass of the movable weight section 120, and can function as a electro-magnetic shield member in some cases (this point will be described later).

### Second Process

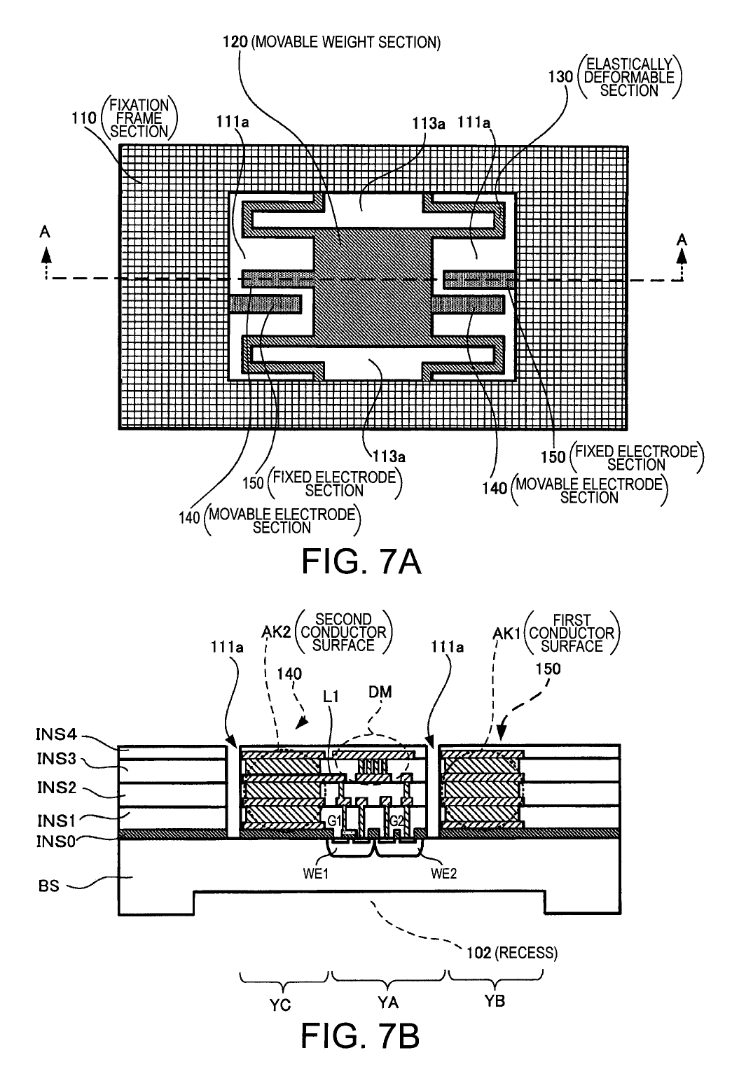

FIGS. 7A and 7B are diagrams respectively showing a planar shape and a cross-sectional structure of the device in the state (a second process) in which a laminate structure on the substrate is patterned. FIG. 7A is a plan view, and FIG. 7B is a cross-sectional view of the device shown in FIG. 7A along the line A-A.

In the second process (process 2), first opening sections 111a, 113a penetrating each of the insulating layers INS0 through INS4 constituting the laminate structure are formed. It should be noted that the first opening sections 111a are opening sections formed around the movable electrode sections 140 and the fixed electrode sections 150. The first opening sections 113a are opening sections formed around the sides not provided with the movable electrode sections 140 out of the four sides (in the case of the plan view) constituting the movable weight section 120. Although the first opening sections are separated into two opening sections 111a and 113a in accordance with the place where the opening sections are formed for the sake of convenience of explanation, these opening sections are formed at the same time, and it is also possible to recognize them as the same opening sections (either one of 111a and 113a).

The first opening sections 111a, 113a are formed by selectively patterning the insulating layers INS0 through INS4 using the anisotropic etching. The etching process is performed as, for example, the insulating film anisotropic etching in which the ratio (H/D) of the etching depth H (e.g., 4 through 6 μm) with respect to the opening diameter D (e.g., 1 μm) becomes a high aspect ratio. As an etchant of this anisotropic etching process, a mixed gas of, for example, CF₄ and CHF₃ can be used. According to this etching process, the laminate structure can be sectionalized into the fixation frame section 110, the movable weight section 120, and the elastically deformable sections 130. It should be noted that since the silicon substrate BS as a foundation is not processed, the sections are in the condition of being connected to the fixation frame section 110 with the silicon substrate BS.

### Third Process

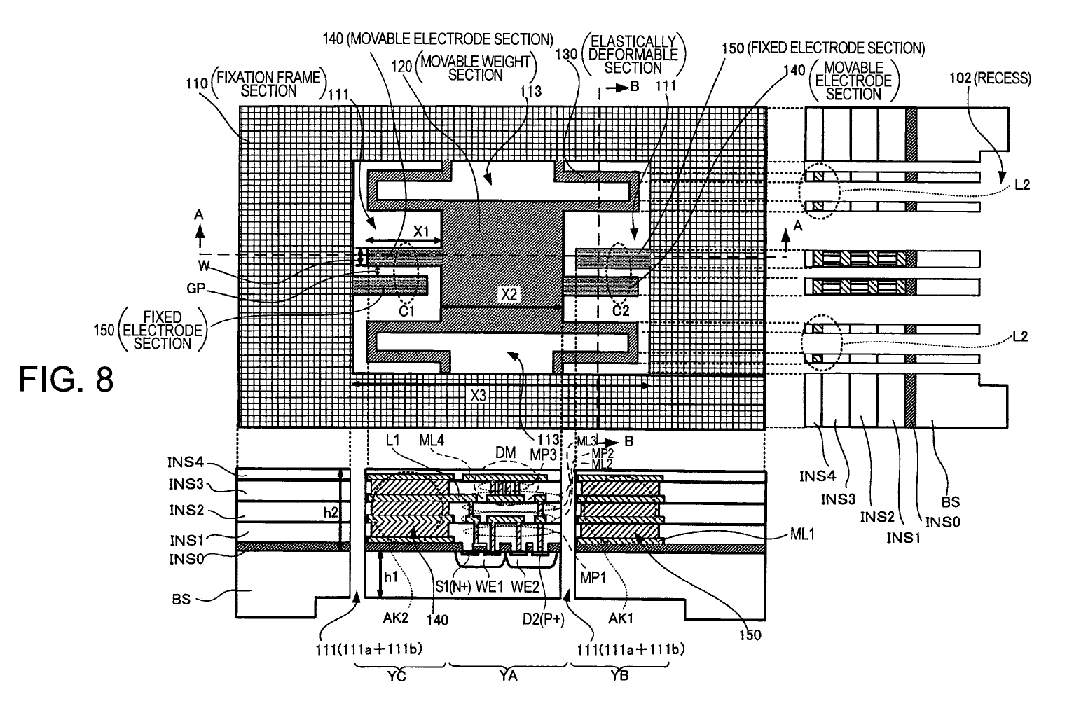

FIG. 8 is a diagram showing the planar shape and the cross-sectional structure of the device in the state (a third process) in which the substrate is patterned to separate the movable weight section and the movable electrode sections from the fixation frame section. The upper left diagram in FIG. 8 is a plan view, the lower left diagram in FIG. 8 is a cross-sectional view along the line A-A of the device shown in the upper left diagram in FIG. 8, and the upper right diagram in FIG. 8 is a cross-sectional view along the line B-B of the device shown in the upper left diagram in FIG. 8.

In the third process (process 3), the etchant is injected via the first opening sections 111a, 113a provided to the laminate structure to perform the anisotropic etching selectively on the silicon substrate BS. By the anisotropic etching on the silicon substrate BS, the second opening sections 111b, 113b penetrating the silicon substrate BS are formed. The first opening sections 111a and the second opening sections 111b are communicated with each other to thereby form the hollow sections 111 around the movable weight section 120. Similarly, the first opening sections 113a and the second opening sections 113b are communicated with each other to thereby form the hollow sections 113 around the movable weight section 120.

As the anisotropic etching method for the silicon substrate BS, a method of performing etching while forming the sidewall protecting film, for example, can be used. As an example, the etching method using the inductively coupled plasma (ICP) disclosed in JP-T-2003-505869 can be adopted. In this method, a passivation step (sidewall protecting film formation) and the etching step are repeatedly executed to thereby form a protective film on the sidewall of the hole formed by etching, thus performing the anisotropic etching only in the depth direction while preventing the isotropic etching by the protective film. As etching conditions in the passivation step, it is preferable to use C₄F₈ or C₃F₆ as the etching gas under the process pressure of 5 through 20 par and the average input coupled plasma power of 300 through 1,000 W. As etching conditions in the etching step, it is preferable to use SF₆ or ClF₃ as the etching gas under the process pressure of 30 through 50 par and the average input coupled plasma power of 1,000 through 5,000 W. Besides the above, reactive ion etching (RIE) for performing the formation of the sidewall protecting film can also be used.

By forming the hollow sections 111, 113, the movable weight section 120 and the movable electrode sections 140 are separated from the fixation frame section 110. The movable weight section 120 is surrounded by the hollow sections (111 and 113), and is coupled to the fixation frame section at the four corners thereof with the elastically deformable sections 130. In other words, as a result, the movable weight section 120 is supported on the fly by the fixation frame section 110 via the elastically deformable sections 130 in a freely vibrating (fluctuating) state. Therefore, the movable weight section 120 (and the movable electrode sections 140) varies the position in accordance with the deformation of the elastically deformable sections 130, and is therefore able to vibrate along the direction of the acceleration applied thereto, for example.

In the hollow sections 111, the movable electrode sections 140 and the fixed electrode sections 150 are disposed so as to face each other. In other words, the movable electrode sections 140 are formed so as to project from the movable weight section 120 toward the hollow sections 111 in a plan view. Similarly, the fixed electrode sections 150 is formed so as to project from the fixation frame section 110 toward the hollow section 111.

In FIG. 8, the movable weight section 120 and the movable electrode sections 140 are separated from the fixation frame section 110, and it is possible to distinguish the movable weight section 120, the fixed electrode sections 150, the movable electrode sections 140, and the elastically deformable sections 130 from each other. In other words, as a result, the laminate structure formed on the substrate BS in the first process shown in FIGS. 6A and 6B is processed by patterning, and is sectionalized into the laminate structures constituting the respective sections. For the sake of convenience of explanation, it is assumed here that the laminate structure constituting the movable weight section 120 is a first laminate structure, the laminate structures constituting the fixed electrode sections 150 are second laminate structures, the laminate structures constituting the movable electrode sections are third laminate structures, and the laminate structures constituting the elastically deformable sections 130 are fourth laminate structures.

In other words, the movable weight section 120 is composed of the substrate BS provided with the impurity layers (e.g., WE1, WE2, S1, D1, S2, and D2) and the first laminate structure. The first laminate structure includes, for example, a plurality of insulating layers (INS0 through INS4) formed in a stacked manner on the substrate BS, and also includes the first conductor layer (e.g., MP1, ML2, MP2, and ML3) as the electrodes (e.g., E1a, E2, and E3), and the second conductor layer (e.g., the third layer wiring layer ML3 drawn from the movable electrodes 140) as the wiring (e.g., the signal wiring L1 and other wiring). As a result, by the impurity layers (e.g., WE1, WE2, S1, D1, S2, and D2) provided to the substrate BS, the first conductor layer (e.g., MP1, ML2, MP2, and ML3), and so on, the amplifier circuit SA is composed, and at the same time, at least one active element (the MOS transistor, in this case) for receiving the detection signal from the capacitive element C1 (C2) is formed, and the input node (the gate G1) of the active element (the MOS transistor) is connected to one (CA, see FIG. 2) or the other (CB, see FIG. 2) of the electrodes of the capacitive elements C1 (C2) via the second conductor layer constituting the signal wiring L1 and so on.

Further, as described above, the second laminate structures constituting the fixed electrode sections 150 are formed so as to project from the fixation frame section 110 toward the hollow sections 111, and are each provided with a conductor layer (a conductor structural object) having a wall-like first conductor surface. The wall-like first conductor surface AK1 (see the portion indicated by surrounding with the dotted line in the lower right part of FIG. 8) forms one (the fixed electrode CA) of the electrodes of the capacitive element (C2, in this case). The first conductor surface AK1 is, for example, a wall-like surface extending along the projection direction of corresponding one of the second laminate structures, and is an opposed surface (specifically, one of the opposed surfaces of the both electrodes CA, CB disposed so as to face each other with a predetermined gap GP, the fixed electrode CA in this case) of the capacitor. For example, in the case in which the laminated conductor layer (a conductor structural object having a predetermined width W in the plan view) provided to each of the second laminate structures extends (is disposed) in the projection direction of the corresponding one of the second laminate structures, it is possible to define the side surface section (i.e., the wall-like surface having a predetermined area) of the conductor structural object as the first conductor surface AK1. The first conductor surface AK1 is covered by, for example, a thin insulating film (it should be noted that this configuration is illustrative only).

In other words, as described above, the first conductor surface AK1 can be formed by, for example, coupling a plurality of conductor layers, the conductor layer (the conductor structural object) is composed of, for example, the conductor layers (ML1 through ML4 in the example shown in FIGS. 6A, 6B, 7A, 7B, and 8) in the first through nth layers (n denotes a natural number equal to or larger than 2) and the contact plugs (MP1 through MP3) for connecting the respective conductor layers coupled integrally to each other, and the sidewall surface of the conductor layer (which can be rephrased as a laminate conductor layer, a laminate conductor structure, a laminate conductor structural object, or a conductor structural object) thus integrally coupled to each other can be used as the first conductor surface AK1, one of the opposed surfaces (electrode surfaces) of the capacitor.

Further, the movable electrode sections 140 are formed using the same manufacturing method as that of the first laminate structure (and the second laminate structures for constituting the fixed electrode sections 150) for constituting the movable weight section 120 in a simultaneous parallel manner, and are constituted by the third laminate structures articulated (namely, formed so as to be integrally connected to each other) to the first laminate structure. The third laminate structures are formed so as to project from the first laminate structure constituting the movable weight section 120 toward the hollow sections 111.

The third laminate structures are each provided with a conductor layer (a conductor structural object) having a wall-like second conductor surface. The wall-like second conductor surface AK2 (see the portion indicated by surrounding with the dotted line in the lower left part of FIG. 8) constitutes the other electrode (the movable electrode) CB of the capacitive element (although the capacitive element corresponds to the capacitor C1 in FIG. 8, since the capacitor C2 is assumed as the fixed electrode here, it is assumed here in the explanation that the capacitive element corresponds to the capacitor C2). The opposed area of the capacitor C2 (C1) is determined in accordance with the opposed area between the wall-like first conductor surface AK1 and the second conductor surface AK2.

The second conductor surface AK2 is, for example, a wall-like surface extending along the projection direction of corresponding one of the third laminate structures, and is an opposed surface (specifically, the other of the opposed surfaces of the both electrodes disposed so as to face each other with a predetermined gap GP, the movable electrode in this case) of the capacitor. For example, in the case in which the laminated conductor layer (a conductor structural object having a predetermined width W in the plan view) provided to each of the third laminate structures extends (is disposed) in the projection direction of the corresponding one of the third laminate structures, it is possible to define the side surface section (i.e., the wall-like surface having a predetermined area) of the conductor structural object as the second conductor surface. The surface of the second conductor surface AK2 is covered by, for example, a thin insulating layer (it should be noted that the invention is not limited thereto).

In other words, the second conductor surface AK2 can be formed by, for example, coupling a plurality of conductor layers, the conductor layer is composed of, for example, the conductor layers (ML1 through ML4 in the example shown in FIGS. 6A, 6B, 7A, 7B, and 8) in the first through nth layers (n denotes a natural number equal to or larger than 2) and the contact plugs (MP1 through MP3) for connecting the respective conductor layers coupled integrally to each other, and the sidewall surface of the conductor layer thus integrally coupled to each other can be used as the second conductor surface AK2, the other of the opposed surfaces (electrode surfaces) of the capacitor.

The length (the electrode length) X1 of the opposed portion between the movable electrode sections 140 and the corresponding fixed electrode sections 150 is, for example, 150 μm, the electrode width W1 is, for example, 3 μm, the gap GP between the electrodes is, for example, 1.5 μm, the lateral width X2 of the movable weight 120 is, for example, 700 μm, and the length X3 of the side adjacent to both of the hollow sections 111, 113 is, for example, 1,000 μm. Further, the thickness h1 of the silicon substrate BS is, for example, 10 μm, and the height h2 of the laminate structure formed on the silicon substrate BS is, for example, 5 μm.

As described above, the movable weight section 120 is provided with the detection circuit 24 (including at least the amplifier circuit SA), and the signal output from the detection circuit is led to the circuit (not shown) provided to the fixation frame section 110 via the output wiring layer L2 disposed along the elastically deformable sections 130. In the upper right diagram in FIG. 8, the output wiring layer L2 is constituted by, for example, the fourth layer wiring (the uppermost layer wiring) (it should be noted that the invention is not limited to this example, but the wiring in another layer can also be used, or it is also possible to use multilayer wiring in order for increasing the cross-sectional area of the wiring).

### Third Embodiment

In the capacitance MEMS sensor manufactured by the manufacturing method described above, the substrate BS remains in each of the movable weight section 120, the elastically deformable sections 130, the movable electrode sections 140 (and the fixed electrode sections 150). As described above, it is possible to form a part (e.g., an impurity layer) of the active element as a constituent of the detection circuit 24 by providing the silicon substrate BS to the movable weight section 120. It should be noted that the advantage provided by the substrate BS is not limited thereto. Specifically, since the substrate BS has a function as an adjustment layer for adjusting the characteristic of the MEMS sensor, the advantage that the manufacturing of a high-performance MEMS sensor becomes easier can be obtained in addition thereto. Hereinafter, advantages and so on of the substrate BS remaining in each of the sections will be considered in a comprehensive manner.

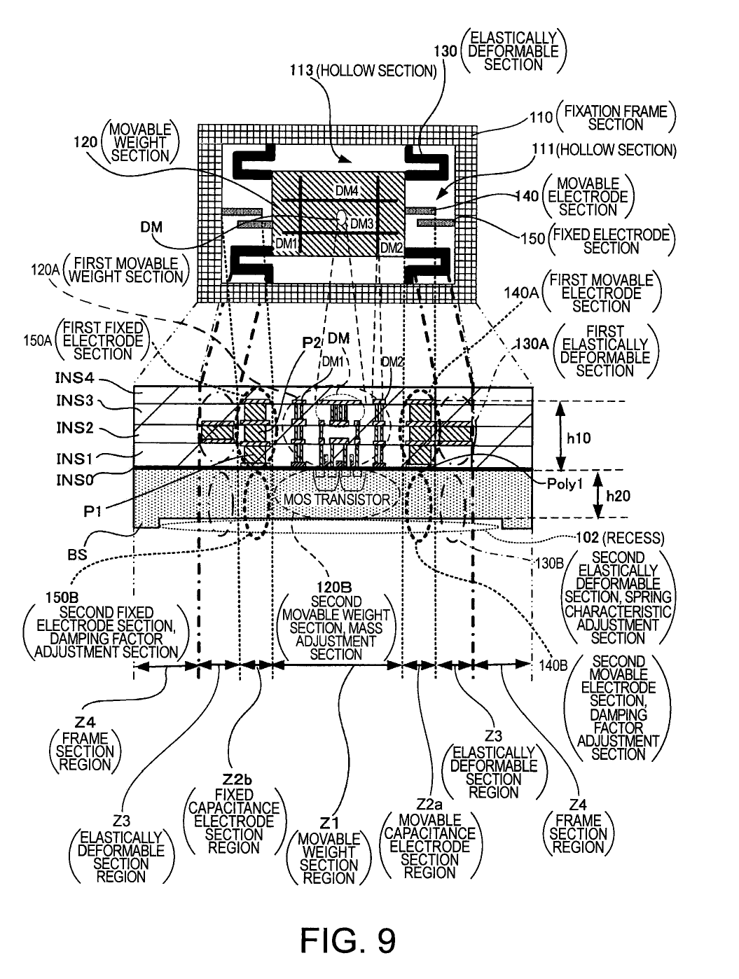

FIG. 9 is a diagram showing a planar shape and a cross-sectional structure of an example (an example thereof having a structure in which the substrate remains in each of the movable weight section, the elastically deformable sections, and the movable electrode sections) of the MEMS sensor (the MEMS acceleration sensor).

The MEMS acceleration sensor shown in FIG. 9 is manufactured using the semiconductor manufacturing method explained as the second embodiment. The movable weight section 120 is provided with the constituents (e.g., the gate oxide film and the gate electrode, the source electrode, the drain electrode, and the signal wiring) of the MOS transistor constituting the detection circuit 24, and is further provided with the dummy wiring (DM, DM1 through DM4), which is an isolated conductor layer, in addition thereto. Here, the dummy wiring DM is provided for the purpose of effectively increasing the mass of the movable weight section 120 and so on as explained above.

Further, the dummy wirings DM1 through MD4 extend in substantially parallel to the four sides, respectively, of the movable weight section 120 (having a quadrangle shape in the plan view), and are each formed of an isolated conductor layer having a wall-like surface (wall-like cross section) (the conductor layer having a multilayer wiring structure composed of a plurality of conductor layers at different layer levels coupled to each other by plugs). The dummy wirings DM1 through DM4 each have a contribution to efficiently increasing the mass of the movable weight section 120, and are further provided with an advantage as an electro-magnetic shield for shielding an electro-magnetic noise emitted from at least a part of the detection circuit 24 provided to the movable weight section 120 and at the same time shielding an electro-magnetic wave coming to the circuit from the outside, in addition thereto. Thus, there is obtained an advantage that the measure against the electro-magnetic noise in the detection circuit 24 (at least a part thereof) is improved, and the reliability of the circuit is enhanced.

In the lower part of FIG. 9, there is shown a cross-sectional structure corresponding to the essential regions of the MEMS acceleration sensor shown in the upper part of FIG. 9. In this cross-sectional structure, the portions constituted by laminate structures are added with an ordinal number of “first,” and the portions constituted by the substrate BS are added with an ordinal number of “second” for the sake of convenience of explanation.

In the drawing, Z1 denotes a movable weight section region, Z2a denotes a movable capacitance electrode section region, Z2b denotes a fixed capacitance electrode section region, Z3 denotes an elastically deformable section region, and Z4 denotes a fixation frame section region.

In the movable weight section region Z1, beneath the laminate structure, there exists a member formed of a part of the silicon substrate BS with the same height (h20). In other words, as a result, the second movable weight section 120B (a mass adjustment section) is provided. As described above, the second movable weight section 120B formed of the silicon substrate BS as a foundation has a contribution to efficiently increasing the mass of the movable weight section 120 to thereby improve the sensitivity of the acceleration sensor.

Similarly, in the movable capacitance electrode section region Z2a, there is provided a second movable electrode section 140B (a damping factor adjustment section) formed of a part of the silicon substrate BS. By providing the second movable electrode section 140B (the damping factor adjustment section, with a height of h20), the overall height (h10+h20) of the movable electrode sections 140 can be adjusted, and thus, it becomes easy to adjust the damping factor D of the movable electrode sections 140 within an appropriate range. It should be noted that the significance of the damping factor D will be described later (see “Explanation of Parameters Related to Characteristics of MEMS Sensor”). Further, by providing the second movable electrode section 140B, warpage of the movable electrode due to the difference in thermal expansion coefficient between the materials of the laminate structure is suppressed. This is helpful for reducing the variation of the opposed area between a pair of capacitance electrodes. It should be noted that the fixed capacitance electrode section region Z2b is also provided with the second fixed electrode section 150B formed of a part of the silicon substrate BS.

Further, in the elastically deformable section region Z3, there are provided second elastically deformable sections (spring characteristic adjustment sections) 130B each formed of a part of the silicon substrate BS. In the elastically deformable sections (the spring sections) 130, unwanted motions such as twisting can be prevented by the second elastically deformable sections (the spring sections) 130B, and further, it is possible to set the mechanical spring constant to be sufficiently larger than the electrical spring constant (the spring constant caused by the electrostatic attractive force in the capacitance section) to thereby realize a desired linear spring characteristic.

Further, in the present embodiment, the laminate structure includes a plurality of conductor layers with different levels of layers, the insulating layers (INS0 through INS4) stacked one another, and the conductor layer as the dummy wiring (DM, DM1 through DM4). Thus, the laminate structure having a multilayer and dense structure including conductive materials and insulating materials is formed. Therefore, it is possible to effectively increase the mass (M) of the movable weight section 120. Further, as described above, it is also possible to assure the electrode sections of the capacitor having a predetermined opposed area in the laminate structure. Further, since the laminate structure can be formed using the manufacturing process (e.g., the CMOS process or the process of a bipolar/CMOS mixed IC) of a semiconductor device, it is easy to make the MEMS sensor and the detection circuit (the integrated circuit section) 24 coexist on the same substrate.

Further, as described above, it is possible to previously provide the recess 102 to the reverse surface of the substrate BS to thereby adjust the thickness of the substrate. In this case, by adjusting the depth of the recess, it is possible to previously adjust the thickness of the substrate portion. As described above, since the substrate is provided with a step by previously forming the recess 102, a space can be prepared under the movable weight section, and thus, the movable weight section can also be prevented from having contact with the installation surface.

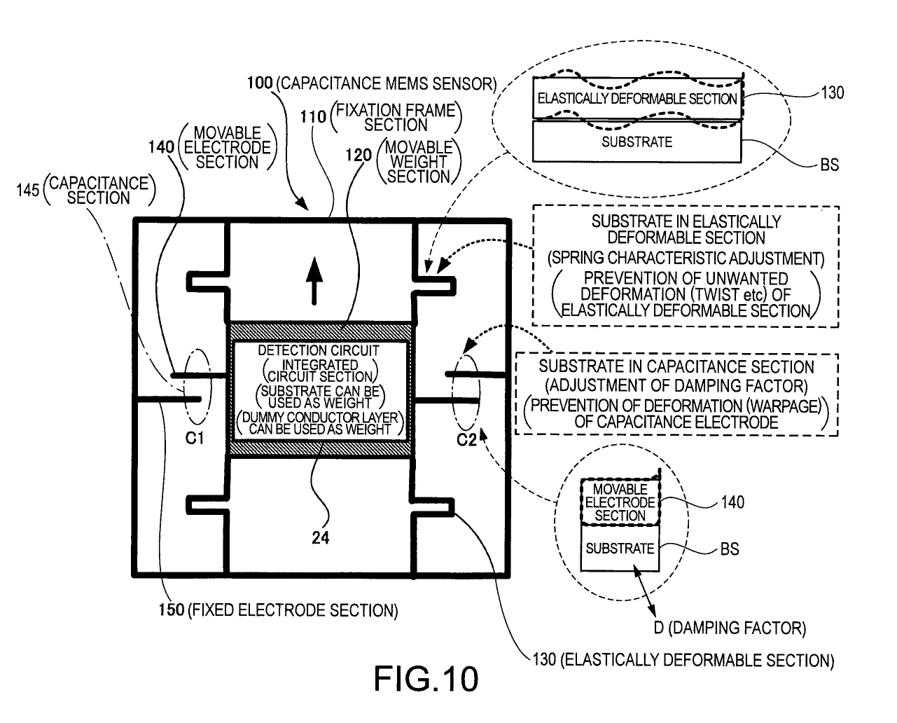

FIG. 10 is a diagram collectively showing examples of the advantage of the MEMS acceleration sensor according to the present embodiment. As shown in the drawing, the detection circuit section (the integrated circuit section) 24 provided to the movable weight section 120 has an advantage as a weight for increasing the overall mass of the movable weight section 120. In other words, the own weight of the integrated circuit itself functions as the weight, and further, the own weight of the substrate BS (the second movable weight section 120B) functions as the weight. Further, if necessary, it is also possible to further increase the mass of the movable weight section 120 by providing the dummy wiring layer (DM, DM1 through DM4).

Further, the damping factor D (i.e., the coefficient representing the significance of the action of the air resistance for suppressing the vibration of the movable weight section 120) can be set within an appropriate range due to the substrate BS (the second movable electrode section 140B) in the capacitance section 145. Further, since the adhesiveness between the substrate BS and the laminate structure is preferable, it is prevented that the warpage is caused by the difference in thermal expansion coefficient between the constituents of the laminate structure in response to the variation of the ambient temperature (the movable electrode with the warpage is illustrated by surrounding with the thick dotted line in the lower right diagram in FIG. 10). This has a contribution to reduction of the variation of the capacitance value of the capacitance section 145.

Further, as shown in the upper right diagram in FIG. 10, the substrate BS (the second elastically deformable section 130B) in the elastically deformable section 130 has a contribution to setting the mechanical spring constant to be sufficiently larger than the electrical spring constant (the spring constant caused by the electrostatic attractive force of the capacitance section) to thereby assure the linearity of the spring. Further, it is also prevented that the twist or the like is caused in the elastically deformable section 130 in response to the acceleration applied thereto. In the upper right diagram of FIG. 10, the state (the undesirable state) in which the elastically deformable section (the spring section) 130 is meandering is illustrated with the thick dotted line. Due to the presence of the substrate BS, the possibility of generation of the meandering state of the elastically deformable section (the spring section) 130 can be reduced.

### Fourth Embodiment

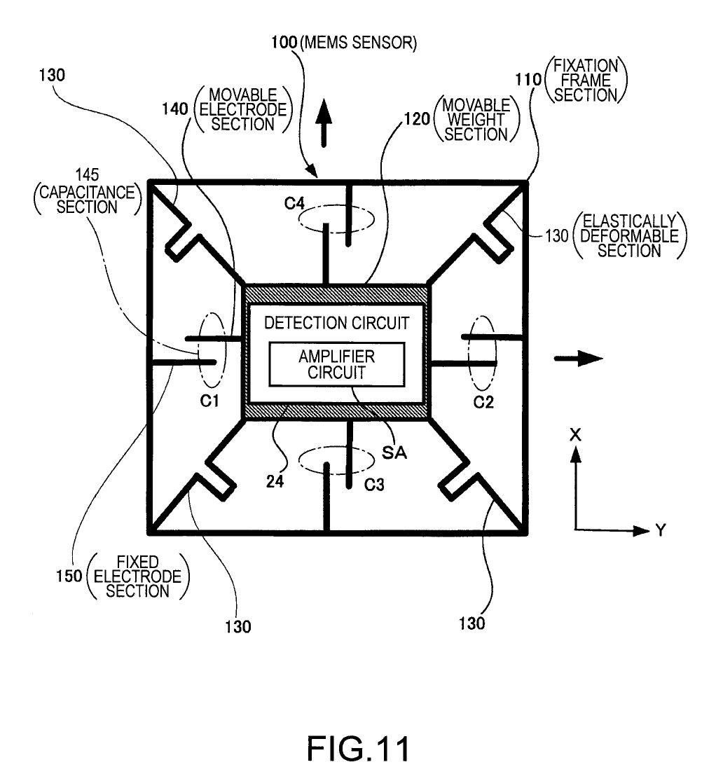

In the present embodiment, the MEMS sensor (here, the MEMS acceleration sensor) having a biaxial detection axis will be explained. FIG. 11 is a plan view of the MEMS sensor (the MEMS acceleration sensor) having a biaxial detection axis.

In the MEMS acceleration sensor 100 shown in FIG. 11, the movable weight section 120 is coupled to the four corners of the fixation frame section 110 with the elastically deformable sections 130, and is therefore capable of vibrating along each of the X-axis and the Y-axis. The capacitive elements C1, C2 are used for detecting the acceleration in the X-axis direction, and the capacitive elements C3, C4 are used for detecting the acceleration in the Y-axis direction. By using the MEMS acceleration sensor having the biaxial detection axis, necessity of providing the sensors for the respective axes can be eliminated. Therefore, the size of the sensor module (e.g., the substrate mounting the sensors and the integrated circuits), for example, can further be reduced. Therefore, the size of the electronic device equipped with the sensor module can also be reduced.

### Explanation of Parameters Related to Characteristics of MEMS Sensor

According to the several embodiments explained hereinabove, freedom of design is enhanced and the detection sensitivity of the physical quantity is also improved. Hereinafter, the parameters related to the characteristics of the MEMS sensor will specifically be explained. Denoting the overall capacitance of the electrode capacitor as C0, the spring constant of the elastically deformable section 130 as K, the inter-electrode gap as d0, the sensitivity S of the MEMS sensor is expressed as follows.

S=C0/d0·(M/K) [F/(m/sec²)]

In other words, the larger the mass of the movable weight section 120 is, the more the sensitivity is improved.

Further, the height of the movable electrode section and the fixed electrode section opposed to each other is denoted as h, the lateral length thereof is denoted as r, and the inter-electrode gap is denoted as d0. In this case, when the gap (the distance between the movable electrode section and the fixed electrode section) of the capacitor varies due to the movement of the movable electrode section, the gas between the electrodes moves up and down, and at that moment, damping (an action for stopping the vibration of the movable electrode section) is caused with respect to the movement of the movable electrode section due to the viscosity of the gas (the air). Denoting the number of pairs of electrodes as n, and the coefficient of viscosity of the gas as μ, the damping factor (D) representing the degree of the damping is expressed as follows.

D=n·μ·r(h/d0)³ [N·sec/m]

In other words, the damping factor D increases in proportion to the cube of the height (h) of the electrode section. Force is acted on the movable electrode section due to the Brownian movement of the gas, which causes the Brownian noise equivalent acceleration. The Brownian noise (BNEA) is expressed as follows, and the numerator of the expression is proportional to the square root of the damping factor (D) proportional to the cube of the height (h) of the movable electrode section.

BNEA=(√(4kBTD))/M [(m/sec²)/√Hz]

Further, since the capacitance MEMS sensor is a structure expressed by a motion equation (see e.g., the formula 1 below) of a free vibration with viscosity damping, it is necessary for the Q value and the resonance frequency (the characteristic frequency) of the structure to be designed to be preferable values. The resonance frequency (the characteristic frequency) ω of the structure performing a free vibration with viscosity damping is determined (see e.g., the formula 2 below) uniquely from the mass M of the movable weight section and the spring constant K of the springs (the elastically deformable sections) for supporting the movable weight section, and further, the Q value representing the sharpness of resonance can be determined (see e.g., the formula 3 below) from a calculating formula further involving the damping factor D. It should be noted that in the formula 3, ξ represents the critical damping coefficient.

$$\begin{matrix}M \ddot{X} + D \dot{X} + KX = 0 & ( 1 ) \\ ω = \sqrt{\frac{K}{M}} & ( 2 ) \\ Q = \frac{1}{2 ξ} = \frac{\sqrt{MK}}{D} & ( 3 )\end{matrix}$$

As is obvious from the formula 3, if the mass M of the movable weight section is increased, the Q value increases, and if the damping factor D increases, the Q value decreases. If the height (i.e., the height of the movable electrode section) of the laminate structure is increased monotonically in order for increasing the mass M, the damping factor D increases in proportion to the cube of the height of the movable electrode section, and therefore, it becomes difficult to keep the Q value in the desired value. It should be noted that according to the embodiments of the invention described above, the modification of making the thickness of the substrate BS different between the movable weight section 120 and the movable electrode section 140, for example, is possible. Therefore, it is also possible to separate the mass M of the movable weight section and the damping factor D in the movable electrode section from each other to thereby independently control the mass M and the damping factor D. Therefore, it is possible to easily perform setting of the damping factor D of the movable electrode section to an appropriate value while keeping the Q value in an appropriate value.

Further, by forming the second elastically deformable section made of the substrate material, the movement of the first elastically deformable section constituted by the laminate structure in the unwanted direction (e.g., a vertical direction) is prevented, and thus the possibility of causing the unwanted movement such as twisting can be reduced. By preventing the unwanted deformation in the elastically deformable sections (the spring sections), the detection sensitivity of the MEMS sensor can further be improved.

Further, it is necessary to make the value of the spring constant in the elastically deformable sections (the spring sections) fall within an appropriate range in order for assuring the desirable resonance characteristic in the vibration section. The effective spring constant is not determined only by the mechanical spring constant of the elastically deformable sections (the spring sections), but is determined comprehensively also taking the electrical spring constant caused by the electrostatic force (the coulomb force) acting between the fixed electrode and the movable electrode in the capacitance electrode section into consideration. Specifically, the effective spring constant is determined by “(mechanical spring constant)−(electrical spring constant).” Therefore, unless the design is made so that the electrical spring constant becomes sufficiently smaller than the mechanical spring constant, it becomes that the formula of the linear spring characteristic expressed as follows is not satisfied, and this point causes constraint on the design.

F=kX (F denotes the force, k denotes the spring constant, and X denotes the displacement)

In contrast, if the structure (the structure in which the silicon substrate material is actively used to thereby optimize the characteristics of the constituents) of the invention is adopted, the value of the lateral width (the length in the lateral direction) of the electrode section can be suppressed to, for example, about 130 μm, which can be fit into the feasible length (within an appropriate range which can be used in the typical design). Further, at the same time, the relationship of (electrical spring constant)<<(mechanical spring constant) can be satisfied due to the rigidity of the second elastically deformable section 130B (see FIG. 9), and the influence of the electrical spring constant can be neglected.

Although the present embodiment is hereinabove explained in detail, it should easily be understood by those skilled in the art that various modifications not substantially departing from the novel matters and the effects of the invention are possible. Therefore, such modified examples should be included in the scope of the invention. For example, a term described at least once with a different term with a broader sense or the same meaning in the specification or the accompanying drawings can be replaced with the different term in any part of the specification or the accompanying drawings.

For example, the MEMS sensor according to the invention is not necessarily limited to those applied to capacitance acceleration sensors, but can also be applied to piezoresistive acceleration sensors. Further, the MEMS sensor according to the invention can also be applied to physical sensors for detecting the variation of the capacitance caused by the movement of the movable weight section. The MEMS sensor according to the invention can be applied to, for example, gyro sensors, or silicon diaphragm type pressure sensors. For example, in the pressure sensor for deforming the silicon diaphragm by the air pressure in the cavity (a hollow chamber), and detecting the variation (or the variation of the resistance of the piezoresistance) of the capacitance due to the deformation, if at least a part of the detection circuit is provided to the silicon diaphragm, the detection sensitivity can be improved.

Further, in the MEMS sensor according to an aspect of the invention, at least the level of the physical quantity can be detected by adopting the opposed electrodes distance of which is variable. It should be noted that the direction in which the physical quantity acts is not detectable with one capacitance. Therefore, it is preferable to provide at least one fixed electrode section, and a plurality of movable electrode sections formed integrally with the movable weight section and moving in at least one axial direction to increase and decrease the distance from the at least one fixed electrode section. This is because, when the plurality of movable electrode sections moves with the movable weight section with respect to the at least one fixed electrode section, one of the two inter-electrode distances increases while the other thereof decreases, thereby the level and the direction of the physical quantity can be detected from the level and the relationship between increase and decrease of the capacitances depending on the inter-electrode distances. Further, the detection axis of the physical quantity is not limited to the uniaxial detection axis or the biaxial detection axis described above, but can be a multiaxial detection axis with three or more axes can also be adopted. Further, it is also possible to adopt a method of detecting the physical quantity using the variation of the opposed area between the electrodes of the capacitor.

The entire disclosure of Japanese Patent Application No. 2009-195121, filed Aug. 26, 2009 is expressly incorporated by reference herein.

What is claimed is:

1. An MEMS sensor comprising:
a fixation frame section;
a movable weight section coupled to the fixation frame section via an elastically deformable section;
a fixed electrode section extending from the fixation frame section toward the movable weight section;
a movable electrode section extending from the movable weight section toward the fixation frame section, and disposed so as to be opposed to the fixed electrode section via a gap;
a capacitance section composed mainly of the fixed electrode section and the movable electrode section; and
an active element provided to the movable weight section.

2. The MEMS sensor according to claim 1, wherein
the movable weight section includes
a substrate provided with an impurity layer, and
a first laminate structure disposed on the substrate,
the first laminate structure includes
an insulating layer, and
a first conductor layer, and
the active element is mainly composed of
the impurity layer, and
the first conductor layer.

3. The MEMS sensor according to claim 2, wherein
the movable electrode section is formed using the first conductor layer, and
the first conductor layer is connected to the movable electrode section and the active element using a second conductor layer.

4. The MEMS sensor according to claim 2, wherein
the first laminate structure is provided with a dummy wiring layer floating electrically.

5. The MEMS sensor according to claim 1, wherein
the active element includes an amplifier circuit adapted to amplify a signal from the capacitance section.

6. A method of manufacturing an MEMS sensor, comprising:
(a) providing an impurity layer to a substrate;
(b) forming a laminate structure including an insulating layer and a conductor layer on the substrate;
(c) patterning the laminate structure using anisotropic etching to form a first opening section from an uppermost layer of the laminate structure to a surface of the substrate; and
(d) injecting an etchant via the first opening section to selectively perform anisotropic etching on the substrate to thereby form a second opening section penetrating the substrate, thus forming
a fixation frame section,
a movable weight section coupled to the fixation frame section via an elastically deformable section,
a fixed electrode section extending from the fixation frame section toward the movable weight section,
a movable electrode section extending from the movable weight section toward the fixation frame section, and disposed so as to be opposed to the fixed electrode section via a gap,
a capacitance section composed mainly of the fixed electrode section and the movable electrode section, and
an active element provided to the movable weight section.

7. An electronic device comprising the MEMS sensor according to claim 1.
